(19) United States
(12) Patent Application Publication
(10) Pub. No.: US 2016/0070294 A1
(43) Pub. Date: Mar. 10, 2016

(54) OSCILLATOR AND DISPLAY DRIVING CIRCUIT INCLUDING THE SAME

(71) Applicants: Kyung-hoon CHUNG, Seoul (KR); Chang-hee SHIN, Gimpo-si (KR); Sang-min LEE, Hwaseong-si (KR); Jun-ho PARK, Yongin-si (KR); Dong-wook SUH, Bucheon-si (KR); Hee-jong KIM, Seoul (KR)

(72) Inventors: Kyung-hoon CHUNG, Seoul (KR); Chang-hee SHIN, Gimpo-si (KR); Sang-min LEE, Hwaseong-si (KR); Jun-ho PARK, Yongin-si (KR); Dong-wook SUH, Bucheon-si (KR); Hee-jong KIM, Seoul (KR)

(21) Appl. No.: 14/750,220

(22) Filed: Jun. 25, 2015

(30) Foreign Application Priority Data
Sep. 5, 2014 (KR) 10-2014-0119367

(51) Int. Cl. G06F 1/04; G09G 5/12; H03K 5/00; H03L 1/02; H03L 7/083; H03K 5/24

(52) U.S. Cl. CPC G06F 1/04; H03L 7/083; H03K 5/24; H03K 5/00006; H03L 1/02; G09G 5/12; G09G 2310/08; G09G 2320/041

(57) ABSTRACT

An oscillator includes a reference current generator to generate a reference current, a reference voltage generator to generate a reference voltage based on the reference current, a comparison voltage generator to generate a comparison voltage obtained by delaying and inverting a clock signal based on the reference current, and a clock signal generator to compare the comparison voltage with the reference voltage and generate the clock signal based on a result of the comparison.

### CROSS-REFERENCE TO RELATED APPLICATION

Korean Patent Application No. 10-2014-0119367, filed on Sep. 5, 2014, entitled, “Oscillator and Display Driving Circuit Including the Same,” is incorporated by reference herein in its entirety.

### BACKGROUND

1. Field

One or more embodiments described herein relate to an oscillator and a display driving circuit including an oscillator.

2. Description of the Related Art

Market demand for displays with improved picture quality, resolution, and multi-functionality and which operate using faster semiconductor devices is continuously increasing. A semiconductor device may operate at various frequencies for driving internal circuits. An oscillator may be used to generate clock signals for at least one of the internal circuits. The clock signal frequency generated for any one internal circuit may adversely affect operation of one or more other internal circuits.

### SUMMARY

In accordance with one or more embodiment, an oscillator includes a reference current generator to generate a reference current; a reference voltage generator to generate a reference voltage based on the reference current; a comparison voltage generator to generate a comparison voltage obtained by delaying and inverting a clock signal based on the reference current; and a clock signal generator to compare the comparison voltage with the reference voltage and generate the clock signal based on a result of the comparison.

A frequency of the clock signal may be based on a voltage level of the reference voltage and a voltage change speed of the comparison voltage. The reference current generator may include a bandgap reference circuit to generate a voltage or a current insensitive to an applied power source voltage or a change in temperature. The reference current generator may generate the reference current to have a substantially uniform slope with respect to a change in temperature.

The reference current generator may include a variable resistor to control a temperature coefficient of the reference current. The reference current generator may control a resistance value of the variable resistor based on a temperature coefficient control signal. The clock signal generator may include a comparator to compare the comparison voltage with the reference voltage and output a result of the comparison, and a bias current applied to the comparator is based on the reference current. A temperature characteristic of a response speed of the comparator may be based on a temperature characteristic of the reference current.

The reference voltage generator may include a first current mirror circuit to generate a first bias current proportional to the reference current by mirroring the reference current; and a reference voltage output circuit including a reference resistance, the reference voltage output circuit to output the reference voltage generated based on the first bias current and the reference resistance.

The reference voltage generator may include a voltage coefficient controller to control a characteristic of the first bias current for a power source voltage. The voltage coefficient controller may vary a mirroring ratio of the first current mirror circuit based on a voltage coefficient control signal.

The comparison voltage generator may include a second current mirror circuit to mirror the reference current and generate a second bias current proportional to the reference current; and a charge and discharge circuit to charge or discharge an internal capacitor based on the second bias current and to generate a first comparison voltage and a second comparison voltage that transitions in a complementarily manner to each other when the clock signal transitions. The comparison voltage generator may include a frequency controller to set a frequency of the clock signal based on a frequency control signal.

The oscillator may include trimming logic to trim a voltage level of the comparison voltage or a delay time of the comparison signal and to change a frequency of the clock signal to a target frequency. Each of the comparison voltage generator and the reference voltage generator may include a current mirror circuit to mirror the reference current and generate a current based on the reference current, the trimming logic is connected to the current mirror circuit of the comparison voltage generator or the reference voltage generator and is to control a mirroring ratio of the current mirror circuit.

The trimming logic may include a thermometer decoder to convert a binary code signal of M bits (where M is a natural number) to a thermometer code signal of 2M-1 bits; and a trimming circuit including a plurality of transistors having substantially a same length and width, the plurality of transistors to turn on or off based on respective bits of the thermometer code signal of 2M-1 bits. The binary code signal of M bits may be set based on a difference between a frequency measurement result of the clock signal and a target frequency.

In accordance with one or more other embodiments, a semiconductor integrated circuit includes an oscillator in accordance with any of the embodiments herein.

In accordance with one or more other embodiments, a signal processing device includes an oscillator in accordance with any of the embodiments described herein.

In accordance with one or more other embodiments, a display device includes an oscillator in accordance with any of the embodiments described herein.

In accordance with one or more other embodiments, an oscillator includes a reference current generator to generate a reference current and to control a temperature characteristic of the reference current; a reference voltage generator to generate a reference voltage based on the reference current; a comparison voltage generator to generate a comparison voltage obtained by delaying and inverting a clock signal based on the reference current; a comparing circuit to compare the comparison voltage with the reference voltage and to output a result of the comparing; and a latch circuit to latch a result of the comparison and to generate the clock signal.

The reference current generator may control a temperature coefficient of the reference current based on a temperature coefficient control signal. The reference current generator may include a variable resistor having a resistance value which changes based on the temperature coefficient control signal. The temperature coefficient control signal may be set based on a difference between a measured temperature characteristic of the oscillator and a target temperature characteristic.

The comparing circuit may include a comparator to receive the comparison voltage and the reference voltage as inputs and to be biased based on the reference current. The comparing circuit may include a first comparator to compare a first comparison voltage with the reference voltage and to generate a first output voltage; a second comparator to compare a second comparison voltage with the reference voltage and to generate a second output voltage, the second comparison voltage to transition in a complementarily manner with respect to the first comparison voltage; and bias currents to be applied to the first comparator and the second comparator are based on the reference current. The bias current applied to the first comparator may be substantially equal to the bias current applied to the second comparator.

In accordance with one or more other embodiments, a display driving circuit includes an oscillator to generate a clock signal; a timing controller to divide a frequency of the clock signal and to generate a timing control signal; and a driving circuit to output a driving voltage based on the timing control signal, wherein the oscillator includes: a bandgap reference circuit to generate a reference current having a temperature characteristic based on a temperature coefficient control signal; and a clock generating circuit to generate a clock signal having a frequency based on the reference current.

The oscillator may include trimming logic to trim a voltage level of the comparison voltage or delay time of the comparison signal and to change a frequency of the clock signal to a target frequency. The oscillator may include a clock generator to generate the clock signal based on a current generated by mirroring the reference current, and trimming logic to linearly vary a mirroring ratio between the generated current and the reference current based on a thermometer code signal.

The clock generating circuit may include a reference voltage generator to receive the reference current and to generate a reference voltage; a comparison voltage generator to receive the reference current and to generate a first comparison voltage and a second comparison voltage that transition in manner complementarily to each other; a comparator to compare the first comparison voltage and the second comparison voltage with the reference voltage and to output a result of the comparison; and a latch circuit to latch the result of the comparison and to output the latched result as the clock signal.

The oscillator may include a selector to select one of a clock signal output from the oscillator or an external clock signal, wherein the timing controller is to generate the timing control signal based on a signal output from the selector. The selection signal may be set based on an operation mode of the driving circuit.

In accordance with one or more other embodiments, an oscillator includes a first generator to generate a reference voltage based on a reference current; a second generator to generate a control voltage based on a clock signal and the reference current; and a third generator to generate the clock signal based on the reference voltage and the control voltage, wherein the clock signal is to be fed back from the third generator to the second generator. The reference voltage may be proportional to the reference current.

The second generator may generate the control voltage by delaying and inverting the clock signal based on the reference current. The third generator may generate the clock signal based on a comparison of the control and reference voltages. The frequency of the clock signal may be based on a voltage level of the reference voltage and a voltage change speed of the control voltage.

### BRIEF DESCRIPTION OF THE DRAWINGS

Features will become apparent to those of skill in the art by describing in detail example embodiments with reference to the attached drawings in which:

FIG. 1 illustrates an embodiment of an oscillator;

FIG. 2 illustrates another embodiment of an oscillator;

FIG. 3 illustrates examples of control signals for the oscillator of FIG. 2;

FIG. 4 illustrates an embodiment of a reference current generator;

FIG. 5 illustrates an embodiment of a variable resistor circuit;

FIG. 6A illustrates an example of temperature characteristics of a reference current, and FIG. 6B illustrates temperature characteristics of an oscillator frequency according to one embodiment;

FIG. 7 illustrates an embodiment of a reference voltage generator;

FIG. 8 illustrates an embodiment of a comparison voltage generator;

FIG. 9 illustrates another embodiment of an oscillator;

FIG. 10 illustrates an embodiment of a trimming unit;

FIG. 11 illustrates an embodiment of a thermometer trimming method;

FIG. 12 illustrates another embodiment of a reference voltage generator;

FIG. 13 illustrates another embodiment of a comparison voltage generator;

FIG. 14 illustrates an embodiment of a signal processing device;

FIG. 15 illustrates another embodiment of a signal processing device;

FIG. 16 illustrates an embodiment of a display device;

FIG. 17 illustrates an embodiment of a display module;

FIG. 18 illustrates an embodiment of a display system; and

FIG. 19 illustrates embodiments of electronic products.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Terms such as “include” or “may include” that may be used in various example embodiments represent the existence of a disclosed corresponding function, operation, or element and do not limit one or more additional functions, operations, or elements. Unless otherwise defined, terms such as “include” and “have” are for representing that characteristics, numbers, steps, operations, elements, and parts described in the specification or a combination of the above exist. It may be interpreted that one or more other characteristics, numbers, steps, operations, elements, and parts or a combination of the above may be added.

In various example embodiments, a term such as “or” includes certain and all combinations of words listed together. It will also be understood that, although the terms first and second, etc., may be used herein to describe various elements, these elements should not be limited by these terms. These terms are only used to distinguish one element from another element. For example, the above terms do not limit an order and/or importance of corresponding elements. The above terms may be used to distinguish one element from another element. For example, a first user device and a second user device are all user devices and represent different user devices. For example, a first element may be named a second element and similarly a second element may be named a first element without departing from the scope of the inventive concept.

It will also be understood that when an element is referred to as being “connected to” or as “contacting” another element, it can be directly connected to or can directly contact the other element. However, intervening elements may also be present. On the other hand, when an element is referred to as being “directly connected to” or as “directly contacting” another element, it can be understood that intervening elements do not exist.

Unless otherwise defined, a singular term may represent a plural term. Unless otherwise defined, all terms (including technical and scientific terms) used herein have the same meaning as commonly understood by one of ordinary skill in the art to which this inventive concept belongs.

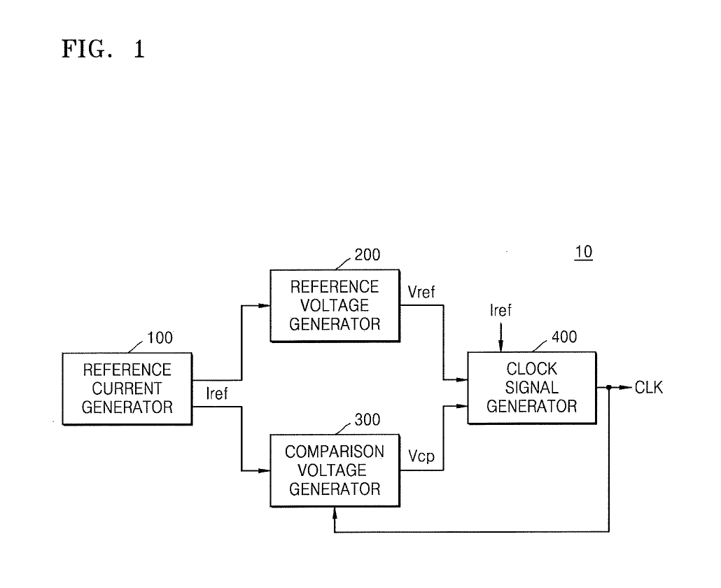

FIG. 1 illustrates an embodiment of an oscillator 10 which includes a reference current generator 100, a reference voltage generator 200, a comparison voltage generator 300, and a clock signal generator 400.

The reference current generator 100 generates a reference current Iref for generating a clock signal CLK. In an example embodiment, the reference current generator 100 may generate the reference current Iref having a uniform current value regardless of a change in process, applied power source voltage, or temperature. In another example embodiment, the reference current generator 100 may generate the reference current Iref to change with a uniform slope for changes in temperature. For example, the reference current generator 100 may control a temperature coefficient of the reference current Iref. For this purpose, the reference current generator 100 may include a bandgap reference circuit that generates a voltage or a current insensitive to the change in temperature or power source voltage. In an example embodiment, the bandgap reference circuit may control an amount of change of the reference current Iref for a change in temperature based on a control signal, for example, a temperature coefficient control signal.

In FIG. 1, for the sake of convenience, the reference current generator 100 is illustrated to generate one reference current Iref. The reference current Iref is applied to the reference voltage generator 200, the comparison voltage generator 300, and the clock signal generator 400. In another example embodiment, the reference current generator 100 may generate a plurality of reference currents with different values. The reference currents generated by the reference current generator 100 may have the same characteristic (e.g., same value) for process, temperature, and/or voltage.

The reference voltage generator 200 receives the reference current Iref and generates a reference voltage Vref based on the reference current Iref. The reference voltage Vref may be proportional to or otherwise based on the reference current Iref. For example, when the reference current Iref increases, the reference voltage Vref may increase. The reference voltage Vref is one of a plurality of parameters that may determine the frequency of the clock signal CLK. In an example embodiment, the reference voltage generator 200 may control a voltage coefficient of the reference voltage Vref for the power source voltage and may compensate for a change in frequency of the clock signal CLK with respect to the change in power source voltage.

The comparison voltage generator 300 receives the reference current Iref and the clock signal CLK, and may generate a comparison voltage Vcp obtained by delaying and inverting the clock signal CLK based on the reference current Iref. The comparison voltage generator 300 may generate at least one comparison voltage Vcp.

The comparison voltage generator 300 may receive the clock signal CLK output from the clock signal generator 400, invert the received clock signal CLK, and delay a time until the clock signal CLK is inverted. For example, when the currently output comparison voltage Vcp is at a low level and the input clock signal CLK transitions from a high level to a low level, the output comparison voltage Vcp gradually increases from the low level to a high level. At this time, the reference current Iref may affect a change of time, that is, a delay time, of the comparison voltage Vcp until the comparison voltage Vcp transitions from the low level to the high level. The delay time, that is, voltage change speed of the comparison voltage Vcp, may be one of the parameters that determines the frequency of the clock signal CLK. In an example embodiment, the comparison voltage generator 300 may control the frequency of the clock signal CLK by controlling the delay time of the comparison voltage Vcp.

The clock signal generator 400 compares the reference voltage Vref with the comparison voltage Vcp and may generate the clock signal CLK based on a result of the comparison. In an example embodiment, an internal circuit of the clock signal generator 400 may be biased based on the reference current Iref. The clock signal CLK is fed back and input to the comparison voltage generator 300. The voltage level of the comparison voltage Vcp gradually changes. However, since the clock signal generator 400 compares a value of the reference voltage Vref with that of the comparison voltage Vcp and outputs the comparison result, the clock signal generator 400 may output a vertically changing signal.

When the comparison voltage Vcp gradually increases from the low level to the high level, the clock signal generator 400 may generate a signal at a low level as the comparison result when the voltage level of the comparison voltage Vcp is lower than the reference voltage Vref. Conversely, the clock signal generator 400 may generate a signal at a high level as the comparison result when the voltage level of the comparison voltage Vcp is higher than the reference voltage Vref. The clock signal generator 400 may output the clock signal CLK based on the comparison result. Therefore, the frequency of the clock signal CLK may vary (or be adjusted) based on the voltage level of the reference voltage Vref and the speed of change of the comparison voltage Vcp. In at least one embodiment, the frequency of the clock signal CLK may be set (or adjusted) regardless of the power source voltage.

In addition to the foregoing considerations, the response delay speed of the clock signal generator 400 may affect the frequency of the clock signal CLK. When the response delay speed of the clock signal generator 400 changes in accordance with a process, temperature, or power source voltage change, the frequency of the clock signal CLK may change.

The response delay speed of the clock signal generator 400 may be determined based on a bias current. In an example embodiment, the clock signal generator 400 may be biased based on the reference current Iref. Thus, when the reference current generator 100 changes a characteristic of the reference current Iref with respect to temperature, a characteristic of the response delay speed of the clock signal generator 400 corresponding to the temperature change may change. As a result, a characteristic of the frequency of the clock signal CLK may change. Therefore, the reference current generator 100 may control the frequency of the clock signal CLK to have a desired value by controlling the temperature coefficient of the reference current Iref.

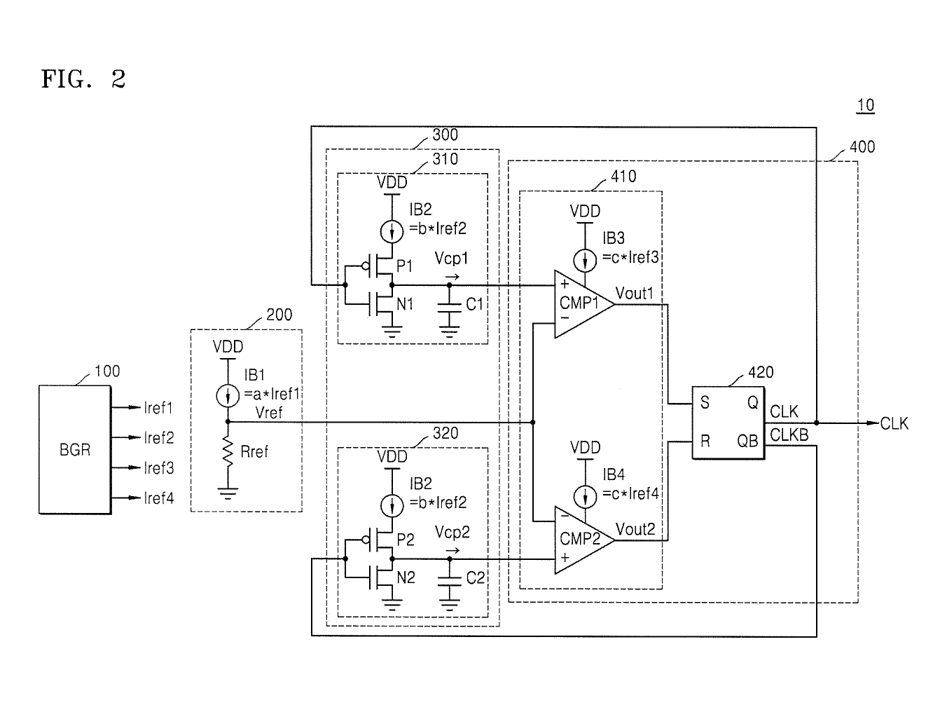

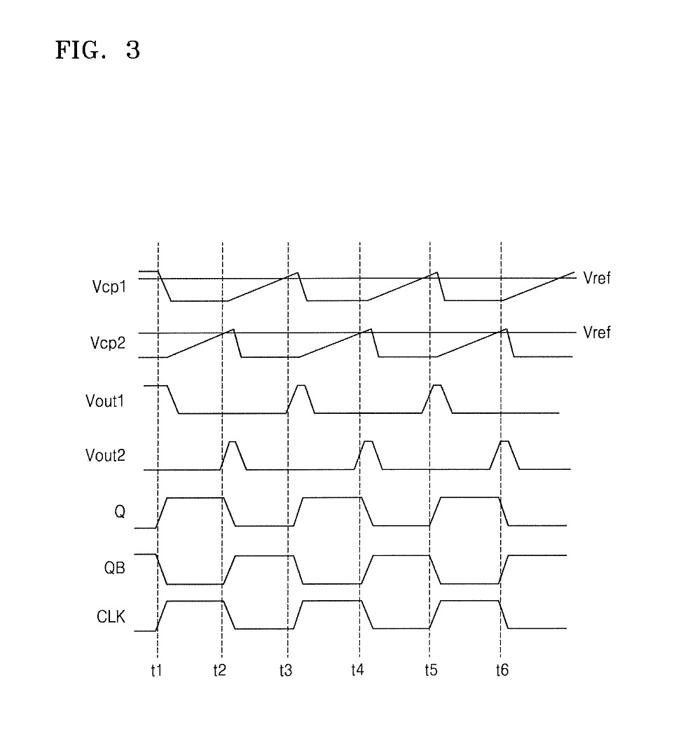

FIG. 2 illustrates another embodiment of the oscillator 10, and FIG. 3 is a timing diagram illustrating an example of control signals for the oscillator 10 in FIG. 2.

Referring to FIG. 2, the oscillator 10 includes a reference current generator 100, a reference voltage generator 200, a comparison voltage generator 300, and a clock signal generator 400.

The reference current generator 100 generates a reference current that is uniform regardless of changes in process, temperature, and power source voltage, or a reference current that changes with a uniform slope, for example, as described with reference to FIG. 1. In the current example embodiment, the reference current generator 100 generates a plurality of reference currents Iref1, Iref2, Iref3, and Iref4 that are output through different circuits. The reference currents Iref1, Iref2, Iref3, and Iref4 may have the same characteristic for process, temperature, and voltage, and in at least one example embodiment may be the same current.

The reference voltage generator 200 includes a reference resistance Rref and may generate a first bias current IB1 by mirroring a first reference current Iref1 and the reference voltage Vref using the reference resistance Rref. Therefore, the reference voltage Vref may be proportional to a resistance value of the reference resistance Rref and the first reference current Iref1. Thus, a temperature characteristic of the reference voltage Vref may be affected by temperature characteristics of the first reference current Iref1 and the reference resistance Rref.

The comparison voltage generator 300 includes a first inverting unit 310 and a second inverting unit 320. The first inverting unit 310 receives the clock signal CLK and may generate a first comparison voltage Vcp1. The second inverting unit 320 receives an inverted clock signal CLKB and may generate a second comparison voltage Vcp2. The first comparison voltage Vcp1 and the second comparison voltage Vcp2 may transition in a manner complementarily to each other.

The first inverting unit 310 may include a first p-type metal-oxide-semiconductor (PMOS) transistor P1 and a first n-type metal-oxide-semiconductor (NMOS) transistor N1 that are serially connected and operate as inverters. The first inverting unit 310 may also include a first capacitor C1 for delaying a change in voltage level of an output voltage, for example, the first comparison voltage Vcp1. As illustrated in FIG. 2, the first capacitor C1 is charged by a second bias current IB2 generated by mirroring the second reference current Iref2. Therefore, the time taken by the first comparison voltage Vcp1 to transition from the low level to the high level may be determined by the second reference current Iref2 and the first capacitor C1.

The structure and operation of the second inverting unit 320 may be similar to the first inverting unit 310. The second inverting unit 320 may include a second PMOS transistor P2 and a second NMOS transistor N2 that are serially connected and operate as inverters. The second inverting unit 320 may also include a second capacitor C2 for delaying a change in voltage level of an output voltage, for example, the second comparison voltage Vcp2. In an example embodiment, sizes of the second PMOS transistor P2 and the second NMOS transistor N2 may be the same as sizes of the first PMOS transistor P1 and the first NMOS transistor N1, respectively. In addition, the capacitance of the second capacitor C2 may be the same as that of the first capacitor C1.

As further illustrated in FIG. 2, the second capacitor C2 is charged by the second bias current IB2, which may be generated by mirroring the second reference current Iref2. Therefore, the time taken by the second comparison voltage Vcp2 to transition from the low level to the high level may be determined by the second reference current Iref2 and the second capacitor C2.

The clock signal generator 400 includes a comparing unit 410 for respectively comparing the first comparison voltage Vcp1 and the second comparison voltage Vcp2 with the reference voltage Vref and for outputting results of the comparison. The clock signal generator 400 may also include a latch circuit 420 for latching output voltages Vout1 and Vout2 and for generating the clock signal CLK. The clock signal generator 400 may further include a plurality of inverters for buffering the clock signal CLK before being output to another circuit.

The comparing unit 410 includes a first comparator CMP1 and a second comparator CMP2. The first comparator CMP1 may output first output voltage Vout1 which corresponds to the result of a comparison between the reference voltage Vref and the first comparison voltage Vcp1. In an example embodiment, the first comparator CMP1 receives the third reference current Iref3 and may be biased to a third bias current IB3 which, for example, may be generated by mirroring the third reference current Iref3. When the first comparison voltage Vcp1 is lower than the reference voltage Vref, the first comparator CMP1 outputs the first output voltage Vout1 at a low level. When the first comparison voltage Vcp1 is greater than or equal to the reference voltage Vref, the first comparator CMP1 may output the first output voltage Vout1 at a high level.

The second comparator CMP2 may output second output voltage Vout2 which corresponds to the result of a comparison between the reference voltage Vref and the second comparison voltage Vcp2. In an example embodiment, the second comparator CMP2 receives the fourth reference current Iref4 and may be biased to a fourth bias current IB4, which, for example, may be generated by mirroring the fourth reference current Iref4. The fourth bias current IB4 may be the same as the third bias current IB3. When the second comparison voltage Vcp2 is lower than the reference voltage Vref, the second comparator CMP2 outputs the second output voltage Vout2 at a low level. When the second comparison voltage Vcp2 is greater than or equal to the reference voltage Vref, the second comparator CMP2 may output the second output voltage Vout2 at a high level.

The latch circuit 420 latches the first output voltage Vout1 and the second output voltage Vout2 and may output the clock signal CLK and the inverted clock signal CLKB. In an example embodiment, the latch circuit 420 may be implemented by an SR latch circuit as illustrated in FIG. 2. In this case, the first output voltage Vout1 is applied to a first input node S of the latch circuit 420 and the second output voltage Vout2 may be applied to a second input node R of the latch circuit 420.

When the voltage levels of the first output voltage Vout1 and the second output voltage Vout2 are different (e.g., when the first output voltage Vout1 is at a high level and the second output voltage Vout2 is at a low level), the latch circuit 420 outputs the clock signal CLK at the same level as the first output voltage Vout1 through a first output node Q and may output the inverted clock signal CLKB at the same level as the second output voltage Vout2 through a second output node QB. When the first output voltage Vout1 and the second output voltage Vout2 are at a low level, the latch circuit 420 may output the clock signal CLK and the inverted clock signal CLKB in the same state as a previous state through the first output node Q and the second output terminal QB, respectively. In another example embodiment, the latch circuit 420 may be implemented by an a different type of latch circuit.

Referring to the timing diagram of FIG. 3, it is assumed that the first output node Q of the latch circuit 420 is initialized to a low level and the second output node QB of the latch circuit 420 is initialized to a high level. In this case, when the first comparison voltage Vcp1 is higher than the reference voltage Vref at time point t1, the first output voltage Vout1 is at a high level and the second output voltage Vout2 is at a low level. As a result, the latch circuit 420 outputs a signal at a high level through the first output node Q and outputs a signal at a low level through the second output node QB. The signals output from the first output node Q and the second output node QB of the latch circuit 420 are respectively applied to the first inverting unit 310 and the second inverting unit 320 of the comparison voltage generator 300. As a result, the first comparison voltage Vcp1 transitions from the high level to the low level and the second comparison voltage Vcp2 transitions from the low level to the high level.

In this case, until the second comparison voltage Vcp2 is greater than or equal to the reference voltage Vref, the first comparator CMP1 and the second comparator CMP2 output signals at a low level and the latch circuit 420 maintains a previous state, in which the first output node Q is at the high level and the second output node QB is at the low level.

When the second comparison voltage Vcp2 is greater than or equal to the reference voltage Vref at time point t2, the first comparator CMP1 outputs the first output voltage Vout1 at a low level and the second comparator CMP2 outputs the second output voltage Vout2 at a high level. As a result, the latch circuit 420 outputs a signal at a low level through the first output node Q and outputs a signal at a high level through the second output node QB. Therefore, the first comparison voltage Vcp1 transitions from the low level to the high level and the second comparison voltage Vcp2 transitions from the high level to the low level. In this case, until the first comparison voltage Vcp1 is greater than or equal to the reference voltage Vref, the first comparator CMP1 and the second comparator CMP2 output signals at a low level and the latch circuit 420 maintains a previous state, in which the first output node Q is at the low level and the second output node QB is at the high level.

When the first comparison voltage Vcp1 is greater than or equal to the reference voltage Vref at time point t3, the first comparator CMP1 outputs the first output voltage Vout1 at a high level and the second comparator CMP2 outputs the second output voltage Vout2 at a low level. As a result, the latch circuit 420 outputs a signal at a high level through the first output node Q and outputs a signal at a low level through the second output node QB. The above operations are repeated so that the clock signal CLK oscillates with a predetermined period.

Referring to FIGS. 2 and 3, the frequency FCLK of the clock signal CLK may be determined based on Equation 1 with the assumption that C=C1=C2

FCLK=b*Iref2/(2*C*Vref) (1)

Since Vref is Ref*(a*Iref1) when Iref1=Iref2, the frequency FCLK and period TCLK of the clock signal CLK may be determined based on Equations 2 and 3.

FCLK=b/(2*C*a*Ref) (2)

TCLK=1/FCLK=2*α*C*RREF, where (α=a/b) (3)

From these equations, it is evident that the frequency FCLK of the clock signal CLK is not related to the power source voltage and may be determined by current mirroring ratios a and b of the first bias current IB1 and the second bias current IB2 for the first reference current Iref1 and the second reference current Iref2, the reference resistance Rref, and the first capacitor C1.

Taking into consideration the response delay time of the comparators CMP1 and CMP2 of the comparing unit 410 and the latch circuit 420, the period TCLK of the clock signal CLK may be determined based on Equation 4.

TCLK=1/FCLK=2*α*C*RREF+2τ(a=a/b) (4)

wherein, τ represents the response delay time of the comparators CMP1 and CMP2 of the comparing unit 410 and the latch circuit 420.

Based on Equation 4, a change in the period TCLK of the clock signal CLK based on a temperature change may be determined based on Equation 5.

∂TCLK/∂T=2α*RREF(∂C/∂T)+2α*C(∂RREF/∂T)+2(∂τ/∂T) (5)

In Equation 5, α is not related to the change in temperature. However, the capacitance of a capacitor C and a resistance value of the reference resistance Rref may vary in accordance with the change in temperature. Therefore, the period TCLK of the clock signal CLK may vary in accordance with the change in temperature. At this time, a change in the period TCLK of the clock signal CLK based on a temperature change may be compensated by controlling the T value, that is, the response delay time of the comparators CMP1 and CMP2 of the comparing unit 410 and the latch circuit 420 with respect to the change in temperature.

In an example embodiment, the comparators CMP1 and CMP2 may be biased based on the third and fourth reference currents Iref3 and Iref4 output from the reference current generator 100. As a result, the response delay speed of the comparators CMP1 and CMP2 may be affected by the third and fourth reference currents Iref3 and Iref4. At this time, as described above, the reference current generator 100 may control temperature characteristics of the reference currents Iref1 to Iref4. Therefore, the oscillator 10 according to at least one example embodiment may control the frequency of the clock signal CLK with respect to temperature by controlling the temperature characteristics of the reference currents Iref1 to Iref4. In addition, when the frequency of the clock signal CLK changes with respect to the temperature change, the oscillator 10 may compensate the change in frequency of the clock signal CLK by controlling the temperature characteristics of the reference currents Iref1 to Iref4.

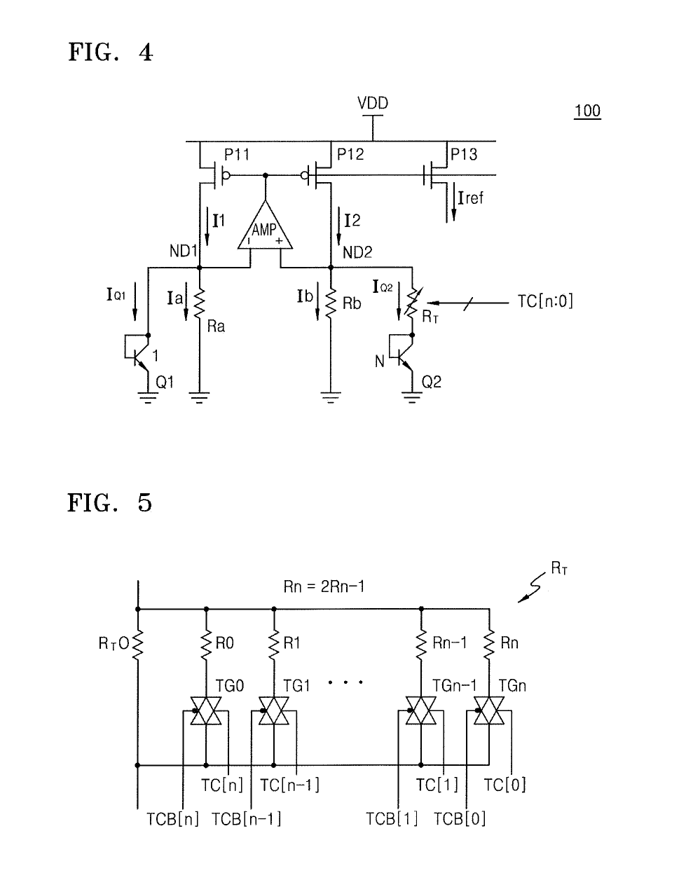

FIG. 4 illustrates an embodiment of the reference current generator 100 which includes a bandgap reference circuit having bipolar junction transistors (BJT) Q1 and Q2, a variable resistor RT, and an operation amplifier AMP. In FIG. 4, for the sake of convenience, one reference current Iref is generated. In another example embodiment, a plurality of reference currents may be generated through respective PMOS transistors. The reference currents may correspond, for example, to first to fourth reference currents Iref1 to Iref4 as illustrated in FIG. 2. Also, the respective PMOS transistors may have the same connection structure as a PMOS transistor P13 through which the reference current Iref flows.

In an example embodiment, a power source voltage VDD of the reference current generator 100 may be the same as or different from a power source voltage VDD (e.g., refer to FIG. 2) of one or more of the reference voltage generator 200, the comparison voltage generator 300, or the clock signal generator 400. For example, in order to reduce current consumption of the oscillator 10, a voltage level of the power source voltage VDD may be lower than that of the power source voltage VDD.

Referring to FIG. 4, when it is assumed that sizes of PMOS transistors P11 and P12 (each of which are connected to an input and output of the operation amplifier AMP) are the same, a node 1 ND1 and a node 2 ND2 have the same voltage due to a feedback operation of the operation amplifier AMP, and resistances Ra and Rb are the same, first and second currents I1 and I2 may be determined based on Equation 6.

I1=I2=VT*ln(N)/RT+VBE/Ra (6)

In Equation 6, VT represents thermal voltage, N represents a ratio between the BJTs Q1 and Q2, and VBE represents a base-emitter voltage of the BIT Q1. The expression VT*ln(N)/RT represents a characteristic proportional to absolute temperature (PTAT) for currents IQ1 and IQ2 that flow through the BJTs Q1 and Q2. The expression VBE/Ra represents a characteristic complementary to absolute temperature (CTAT) for currents Ia and Ib that flow through the resistances Ra and Rb.

The reference current Iref may be proportional to the currents I1 and I2 and may have the same characteristic as the currents I1 and I2 for process, temperature, and voltage. When it is assumed that sizes of the PMOS transistors P11, P12, and P13 are the same, the reference current Iref may have the same value as the first and second currents I1 and I2. Therefore, the temperature characteristics of the reference currents Iref1 and Iref2 may be controlled based on a combination of the PTAT component and the CTAT component in Equation 6.

The amount of change in temperature of the reference current Iref may be determined based on Equation 7.

∂Iref/∂T=(ln(N)/RT)(∂VT/∂T)+(1/Ra)(3VBE/∂T) (7)

Here, since amounts of temperature change of VT and VBE are much larger than (VT/RT)(∂RT/∂T) and (VBE/Ra)(∂Ra/∂T), the reference current generator 100 may control the amount of change in temperature relating to the reference current Iref (e.g., a temperature coefficient) by controlling the resistance value of the variable resistor RT.

In the current example embodiment, the reference current generator 100 may easily control the temperature characteristic of the reference current Iref by varying the resistance value of the variable resistor RT through digital control. For example, the reference current generator 100 may control the resistance value of the variable resistor RT in response to a temperature coefficient control signal TC[n:0]. The temperature coefficient control signal TC[n:0] may be changed based on a difference between a measured temperature characteristic (e.g., a temperature characteristic of the frequency of the clock signal CLK generated by the oscillator 10) of the oscillator 10 and a target temperature characteristic.

In one example embodiment, when the temperature coefficient control signal TC[n:0] is set as a default value and the measured temperature characteristic of the oscillator 10 is different from the target temperature characteristic, the temperature coefficient control signal TC[n:0] may be changed so that the temperature characteristic of the clock signal CLK is the same as the target temperature characteristic. Because the temperature coefficient of the reference current Iref changes in accordance with the temperature coefficient control signal TC[n:0], the temperature characteristic of the oscillator 10 may therefore vary or be adjusted.

FIG. 5 illustrates an embodiment of the variable resistor RT in FIG. 4. Referring to FIG. 5, the variable resistor RT may include a default resistance R_{T}0 and additional resistances R0 to Rn selectively connected to the default resistance R_{T}0 in parallel. The additional resistances R0 to Rn are respectively connected to switching devices TG0 to TGn, that operate in response to respective bits of the temperature coefficient control signal TC[n:0]. When the switching devices TG0 to TGn are turned on, the additional resistances R0 to Rn may be connected to the default resistance R_{T}0 in parallel.

In FIG. 5, the switching devices TG0 to TGn are transmission gates. In another example embodiment, the switching devices TG0 to TGn may be other devices that perform switching operations in response to an applied signal. Also, in one example embodiment, the resistance values of adjacent ones of the additional resistances may differ by a predetermined factor. For example, the resistance value of the second additional resistance R2 may be twice the resistance value of the first additional resistance R1, e.g., may differ by a factor of 2.

When the number of additional resistances R0 to Rn connected to the default resistance RT0 increases, the resistance value of the variable resistor RT is reduced. When the number of additional resistances R0 to Rn is reduced, the resistance value of the variable resistor RT may increase. When resistance values of adjacent additional resistances differs by a factor of 2, the resistance value of the variable resistor RT may be linearly reduced or increased as the value of the temperature coefficient control signal TC[n:0] is increased or reduced.

In another example embodiment, the variable resistor RT may have a different circuit structure in which the resistance value linearly changes due to the temperature coefficient control signal IC [n:0].

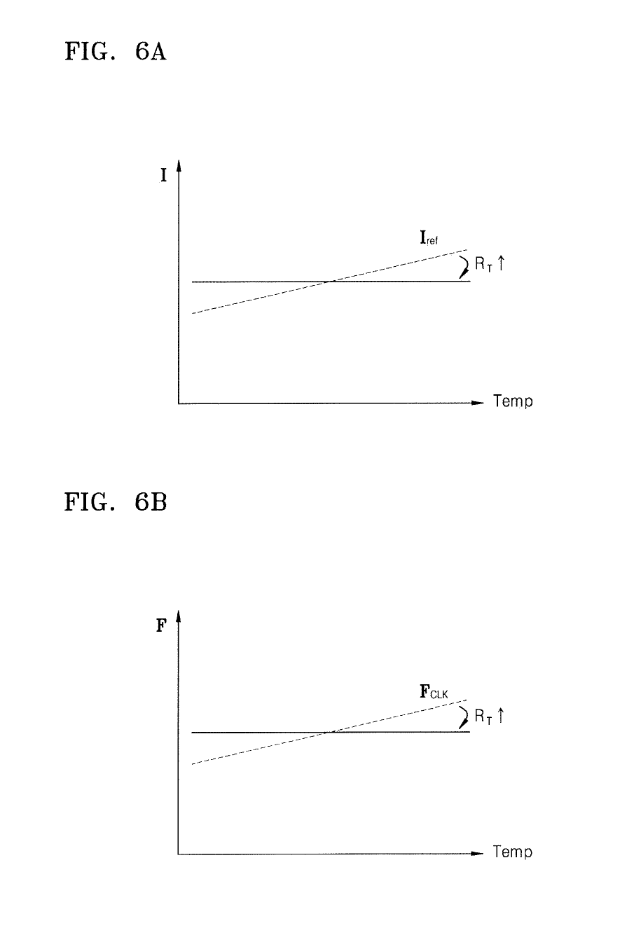

FIGS. 6A and 6B are graphs of temperature characteristics of a reference current and an oscillator frequency according to example embodiments. In FIGS. 6A and 6B, the dotted lines respectively represent the reference current Iref and the frequency FCLK of the clock signal CLK generated by the oscillator 10 before the resistance value of the variable resistor RT is changed. The solid lines respectively represent the reference current Iref and the frequency FCLK of the clock signal CLK that change based on a change in the resistance value of the variable resistor RT. Although the reference current Iref does not change in accordance with a temperature, the frequency FCLK of the clock signal CLK may change in accordance with the temperature, for example, due to influence of a process change one or more circuit elements, e.g., resistors, capacitors, or transistors.

Referring to Equation 5, the temperature characteristic of the frequency FCLK of the clock signal CLK may be changed by controlling the response delay time of the comparators CMP1 and CMP2 and the latch circuit 420 with respect to change in temperature. The response delay time of the comparators CMP1 and CMP2 may be determined based on the bias current. Therefore, the temperature characteristic of the frequency FCLK of the clock signal CLK may be controlled by the temperature characteristic of the reference current Iref.

Therefore, as illustrated in FIGS. 6A and 6B, the frequency FCLK of the clock signal CLK may be controlled to be uniform regardless of a change in temperature, by changing the resistance value of the variable resistor RT and controlling the temperature characteristic (e.g., the temperature coefficient) of the reference current Iref. FIG. 6A illustrates that the temperature coefficient of the reference current Iref is reduced when the resistance value of the variable resistor RT increases. Conversely, when the resistance value of the variable resistor RT is reduced, the temperature coefficient of the reference current Iref may increase.

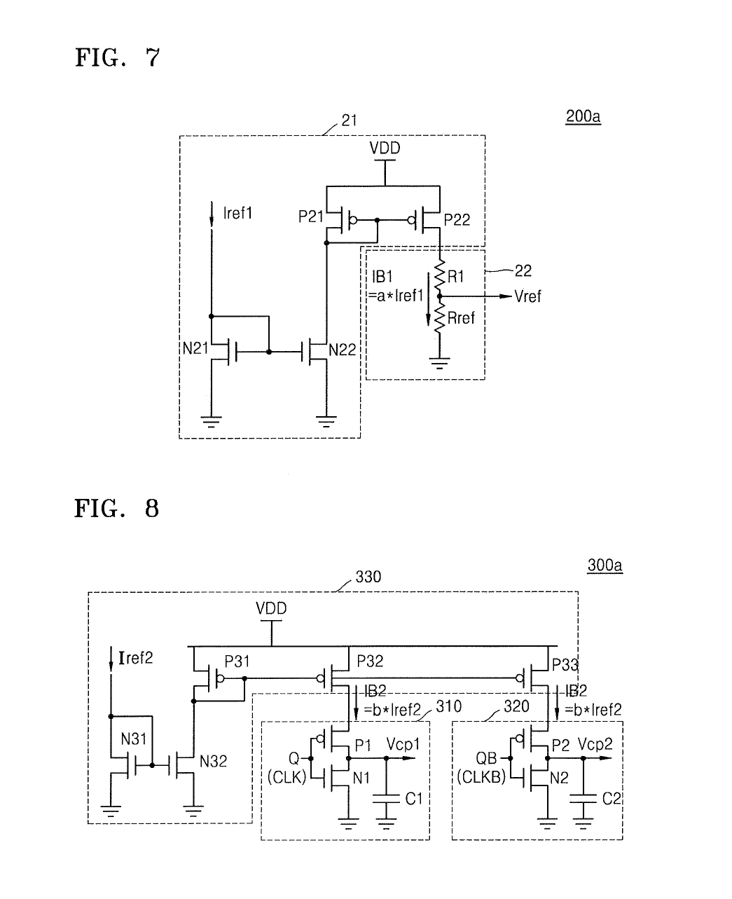

FIG. 7 illustrates an embodiment of a reference voltage generator 200a which includes a first current mirroring unit 21 and a reference voltage outputting unit 22. The first current mirroring unit 21 mirrors an applied first reference current Iref1 and may generate a first bias current IB1. A mirroring ratio a may be determined, for example, based on a size ratio of corresponding transistors N21, N22, P21, and P22. The reference voltage outputting unit 22 includes a first resistance R1 and a reference resistance Rref and may output a voltage of a connection node between the first resistance R1 and the reference resistance Rref as a reference voltage Vref. The reference voltage Vref may be proportional to the first bias current IB1 or the reference resistance Rref.

FIG. 8 illustrates an embodiment of a comparison voltage generator 300a which includes a second current mirroring unit 330, a first inverting unit 310, and a second inverting unit 320. The second current mirroring unit 330 mirrors an applied second reference current Iref2 and may generate a second bias current IB2. A mirroring ratio b may be determined based on a size ratio of transistors N31. N32. P31, and P32.

The first inverting unit 310 and the second inverting unit 320 may be referred to as a charge and discharge circuit, respectively. The first inverting unit 310 delays and inverts a clock signal CLK and outputs the delayed and inverted clock signal CLK as a first comparison voltage Vcp1. When the clock signal CLK is at a low level, a voltage level of the first comparison voltage Vcp1 may gradually increase as the second bias current IB2 charges a first capacitor C1. When the clock signal CLK is at a high level, charges charged in the first capacitor C1 are discharged through a first NMOS transistor N1. As a result, the voltage level of the first comparison voltage Vcp1 may be reduced.

When the voltage level of the first comparison voltage Vcp1, that is reduced through the first NMOS transistor N1, is compared with the voltage level of the first comparison voltage Vcp1, that is increased by the second bias current IB2, the speed at which the voltage level of the first comparison voltage Vcp1 is reduced may be greater than the speed at which the voltage level of the first comparison voltage Vcp1 is increased. Therefore, the voltage level of the first comparison voltage Vcp1 may be slowly increased and rapidly reduced.

The second inverting unit 320 delays and inverts an inverted clock signal CLKB and outputs the delayed and inverted clock signal CLKB as a second comparison voltage Vcp2. When the inverted clock signal CLKB is at a low level, a voltage level of the second comparison voltage Vcp2 may gradually increase as the second bias current IB2 charges a second capacitor C2. When the inverted clock signal CLKB is at a high level, charges charged in the second capacitor C2 are discharged through a second NMOS transistor N2. As a result, the voltage level of the second comparison voltage Vcp2 may be reduced. The voltage level of the second comparison voltage Vcp2 may be slowly increased and rapidly reduced.

In an example embodiment, the first inverting unit 310 and the second inverting unit 320 may have the same structure. Additionally, or alternatively, the transition period of the first comparison voltage Vcp1 may be the same as that of the second comparison voltage Vcp2.

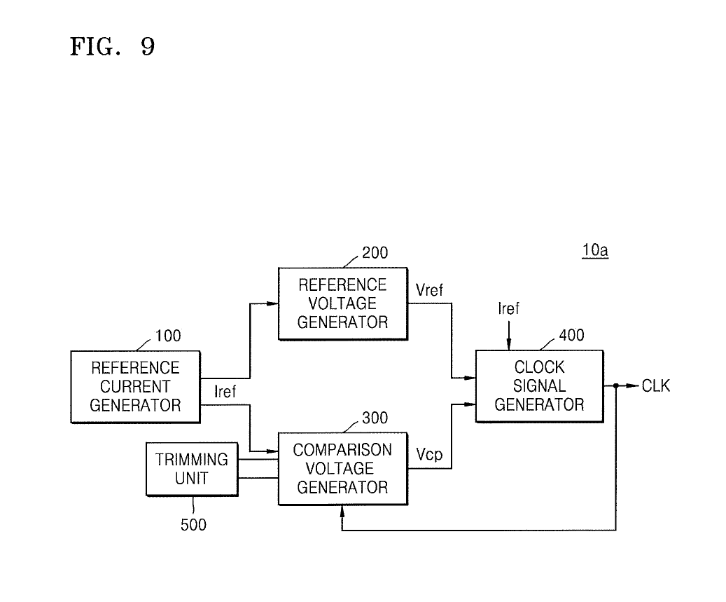

FIG. 9 illustrates another embodiment of an oscillator 10a which includes a reference current generator 100, a reference voltage generator 200, a comparison voltage generator 300, a clock signal generator 400, and a trimming unit 500. The structure and operation of the oscillator 10a may be similar to those of the oscillator 10 of FIG. 1, with the exception of the addition of a trimming unit 500. The trimming unit 500 may be logic implemented in hardware, software, or both.

The trimming unit 500 may improve frequency distribution by moving the frequency of the clock signal CLK to a target frequency. When the frequency of the clock signal CLK is different from the target frequency, the trimming unit 500 may move the frequency of the clock signal CLK to the target frequency, for example, by performing digital control.

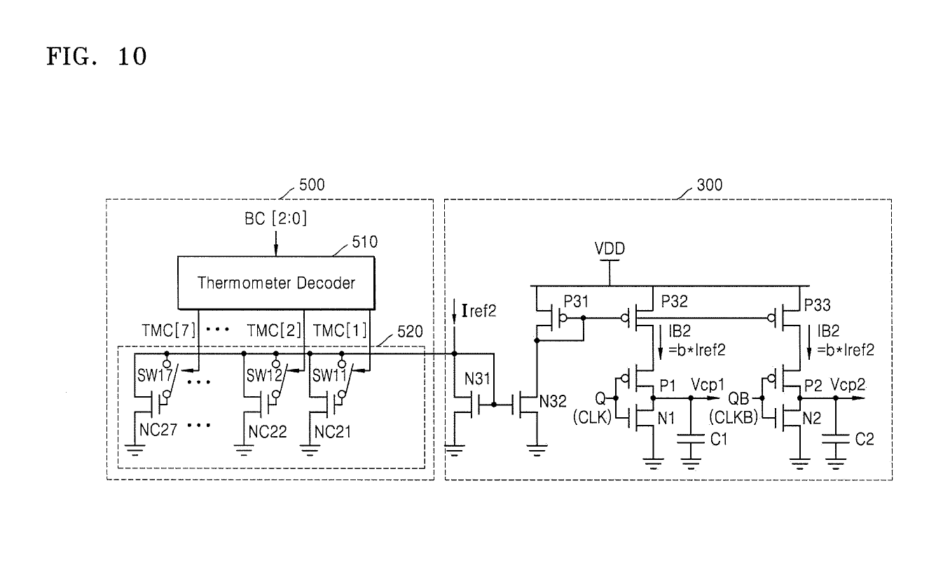

FIG. 10 illustrates an embodiment of the trimming unit 500 which performs digital control of the frequency the clock signal CLK. For the sake of convenience, the comparison voltage generator 300 is also illustrated. Referring to FIG. 10, the trimming unit 500 includes a thermometer decoder 510 and a trimming circuit 520. When a binary code BC of M bits is applied (e.g., from an external source), the thermometer decoder 510 converts the binary code BC of M bits to a thermometer code TMC of 2M-1 bits.

The binary code BC of M bits may be set based on a difference between the frequency measurement result of the clock signal CLK and the target frequency. For example, the binary code BC may be a value that controls the frequency of the clock signal CLK to move to the target frequency. In FIG. 10, a binary code BC[2:0] of 3 bits is applied so that a thermometer code TMC[7:1] of 7 bits is output from the thermometer decoder 510. In another embodiment, the binary code BC may have a different number of bits and/or the binary code may be converted to a thermometer code TMC of a different number of bits.

The trimming circuit 520 may include a plurality of transistors NC11 to NC17 and a plurality of switches SW11 to SW17. Sizes of the transistors NC11 to NC17 may, for example, be the same. The transistors NC11 to NC17 may be connected to the first NMOS transistor N31 of the comparison voltage generator 300 in parallel. The transistors NC11 to NC17 may be turned on or off in response to the respective bits of the thermometer code TMC[7:1].

When the transistors NC11 to NC17 are turned on in response to the thermometer code TMC[7:1], the total size of the transistors through which the first reference current Iref1 flows increases. Therefore, a mirroring ratio b of the second bias current IB2 changes, which produces a change in the current value of the second bias current IB2. As a result, the frequency of the clock signal CLK changes.

The trimming unit 500 according to the current embodiment controls the transistors NC11 to NC17 (which have the same size) to be turned on using a thermometer method. Through this method, the frequency of the clock signal CLK may linearly change in accordance with an increase in the binary code BC[2:0].

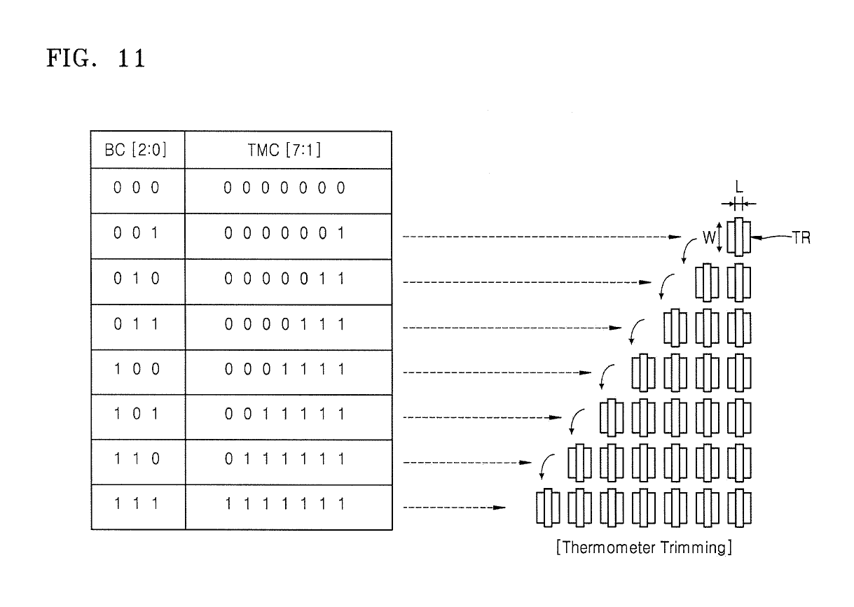

FIG. 11 illustrates a table and other features corresponding to one embodiment a thermometer trimming method. In this method, the thermometer decoder 510 of FIG. 10 decodes the binary code BC[2:0] of 3 bits to a thermometer code TMC[7:1] of 8 bits. When the bits of the binary code BC[2:0] are sequentially increased, the number of bits of the thermometer code TMC[7:1] that change from 0 to 1 sequentially increases. As a result, the number of turned-on transistors TR increases. Since the transistors TR have the same width W and length L, the matching characteristic among them is high.

Therefore, when the frequency of the clock signal CLK is controlled by the thermometer trimming method, the linearity of the change in frequency may increase in comparison with the case where the frequency of the clock signal CLK is controlled using a binary trimming method, in which on/off of transistors of different sizes are controlled and a total size of turned-on transistors is controlled.

In FIGS. 9 and 10, the trimming unit 500 is illustrated as being connected to the comparison voltage generator 300 in parallel. In another example embodiment, the trimming unit 500 may be connected to the reference voltage generator 200 in parallel and the frequency of the clock signal CLK may be changed by changing the mirroring ratio a of the first current mirroring unit 21 (e.g., of FIG. 7) in accordance with an applied binary code BC.

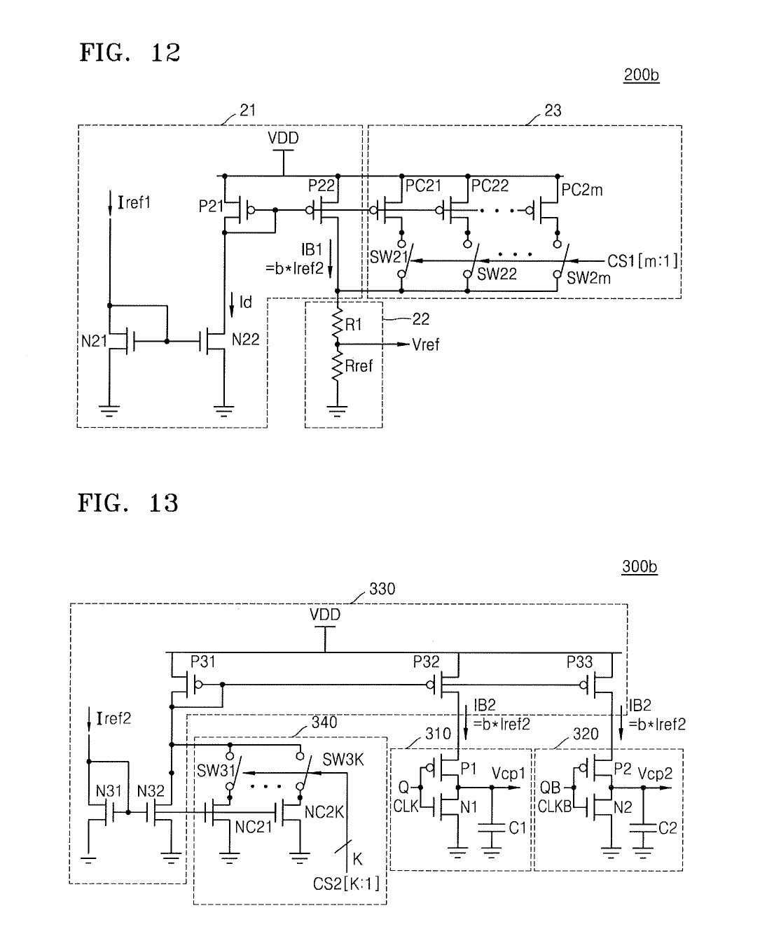

FIG. 12 illustrates an embodiment of a reference voltage generator 200b which includes a first current mirroring unit 21, a reference voltage outputting unit 22, and a voltage coefficient controller 23. Different from FIG. 7, the reference voltage generator 200b in FIG. 12 includes voltage coefficient controller 23.

The voltage level of the reference voltage Vref generated by the reference voltage generator 200b is determined by values of the first bias current IB1 and the reference resistance Rref. The first bias current IB1 is generated by mirroring the first reference current Iref1. As a result, the voltage level of the reference voltage Vref may not ideally change due to an increase and reduction in a power source voltage VDD.

However, when the power source voltage VDD increases, source-drain voltages of the second NMOS transistor N22 increases and a drain current Id of the second NMOS transistor N22 increases due to a channel length modulation effect. Therefore. since the first bias current IB1 also increases, the voltage level of the reference voltage Vref may increase.

The voltage coefficient controller 23 may vary the mirroring ratio a of the first bias current IB1 based on a voltage coefficient control signal CS1[m:1]. As a result, a voltage coefficient of the first bias current IB1 and the voltage coefficient of the reference voltage Vref may be controlled.

As illustrated in FIG. 12, the voltage coefficient controller 23 may include a plurality of transistors PC21 to PC2m and switches SW21 to SW2m serially connected to respective ones of the transistors PC21 to PC2m. When the switches SW21 to SW2m are turned on based on respective bits of the voltage coefficient control signal CS1[m:1], the mirroring ratio a of the first bias current IB1 may vary, or be adjusted, since current flows through the transistors PC21 to PC2m corresponding to the switches SW21 to SW2m.

When the power source voltage VDD of the oscillator 10 changes, the frequency of the clock signal CLK may change. As described with reference to FIG. 2, the frequency of the clock signal CLK is inversely proportional to the voltage level of the reference voltage Vref. Therefore, the reference voltage generator 200b according to the present embodiment may compensate for a change in frequency of the clock signal CLK for the power source voltage VDD by controlling the voltage coefficient of the reference voltage Vref through digital control. For example, when the frequency of the clock signal CLK increases as a voltage level of the power source voltage VDD increases, the change in frequency of the clock signal CLK may be compensated by controlling the voltage coefficient control signal CS1[m:1] so that the voltage coefficient of the reference voltage Vref increases. The voltage coefficient control signal may be controlled, for example, by a user or by a control circuit and/or software.

FIG. 13 illustrates an embodiment of a comparison voltage generator 300b which include a second current mirroring unit 330, a first inverting unit 310, a second inverting unit 320, and a frequency controller 340. Different from the comparison voltage generator 300a, the comparison voltage generator 300b includes frequency controller 340. The frequency controller 340 may be programmed to control the frequency of the clock signal CLK by controlling a mirroring ratio b of the second current mirroring unit 330 in response to a frequency control signal CS2[k:1].

As illustrated in FIG. 13, the frequency controller 340 includes a plurality of NMOS transistors NC21 to NC2k and a plurality of switches SW31 to SW3k respectively connected to the NMOS transistors NC21 to NC2k. The switches SW31 to SW3k may be turned on or off based on respective bits of the frequency control signal CS2[k:1].

When the switches SW31 to SW3k are turned on, the mirroring ratio b of the second bias current IB2 increases since current flows through the NMOS transistors NC21 to NC2k corresponding to the switches SW31 to SW3k. An increase in the mirroring ratio b of the second bias current IB2 may, in turn, increase the current value of the second bias current IB2. Since the frequency of the clock signal CLK may vary due to the current value of the second bias current IB2, the frequency of the clock signal CLK may change when the frequency control signal CS2[k:1] changes.

FIG. 14 illustrates an embodiment of a signal processing device 1000 which includes an oscillator according to any of the aforementioned embodiments and a logic circuit 20. The signal processing device 1000 may be or include, for example, a display device, a synchronous memory, and/or a clock signal based processor. In one example embodiment, the signal processing device 1000 may be implemented by a semiconductor chip including the oscillator and the logic circuit 20. For the sake of illustration, the signal processing device 1000 will be described as including oscillator 10.

The oscillator 10 outputs the clock signal CLK for driving the logic circuit 20. The oscillator 10 generates the clock signal CLK having a uniform frequency regardless of a change in process, temperature, and power source voltage as described above with reference to FIGS. 1 to 13. In addition, when the frequency of the clock signal CLK changes in accordance with temperature and power source voltage due to passive devices in a circuit, the oscillator 10 internally compensates for the change in frequency so that the frequency does not change with the temperature and power source voltage changes.

The logic circuit 20 may control operation of the signal processing device 1000 based on the clock signal CLK. For example, when the signal processing device 1000 is the memory device, the logic circuit 20 may output command and writing data DATA for controlling a writing operation of data in response to the clock signal CLK from the oscillator 10. In addition, the logic circuit 20 may generate a command for controlling a reading operation or a verifying operation of the signal processing device 1000.

In another example embodiment, when the signal processing device 1000 is implemented by a display device, the logic circuit 20 may be a timing controller for controlling timing of the display device. In this case, the logic circuit 20 may generate a timing control signal by dividing the frequency of the clock signal CLK output from the oscillator 10.

Since the clock signal CLK output from the oscillator 10 may have a uniform frequency regardless of changes in process, temperature, and power source voltage, the logic circuit 20 that operates in response to the clock signal CLK may stably operate, even though temperature or power source voltage changes.

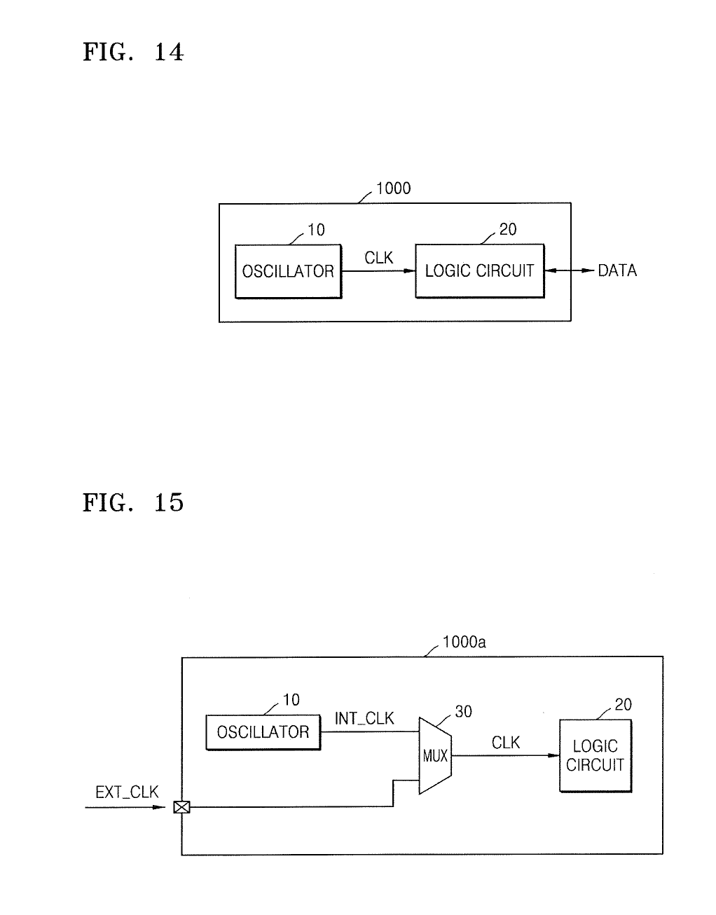

FIG. 15 illustrates another embodiment of a signal processing device 1000a which includes an oscillator that may correspond to any of the aforementioned oscillator embodiments. For the sake of illustration, the signal processing device 1000a will be described as including oscillator 10.

Referring to FIG. 15, the signal processing device 1000a includes an oscillator 10, a logic circuit 20, and a selector 30. The signal processing device 1000a receives an external clock EXT_CLK, for example, from an external source. The oscillator 10 generates an internal clock INT_CLK. The selector 30 (e.g., a multiplexer MUX) selects at least one of the internal clock INT_CLK output from the oscillator 10 or the external clock EXT_CLK, and provides the selected clock to the logic circuit 20 as the clock signal CLK.

In an example embodiment, when the external clock EXT_CLK is received, the selector 30 provides the external clock EXT_CLK to the logic circuit 20 as the clock signal CLK, and the logic circuit 20 operates based on the external clock EXT_CLK. When the external clock EXT_CLK is not received, the oscillator 10 operates and outputs the internal clock INT_CLK, and the logic circuit 20 operates based on the internal clock INT_CLK.

In an example embodiment, the signal processing device 1000a is or includes a display device and receives the external clock EXT_CLK together with display data from a host. The selector 30 selects one of the external clock EXT_CLK or the internal clock INT_CLK based on a selection signal. The selection signal may be set, for example, in accordance with an operation mode of the signal processing device 1000a. In various example embodiments, when the signal processing device 1000a receives a moving picture from the host and the moving picture is displayed, the logic circuit 20 may operate based on the external clock EXT_CLK. When the signal processing device 1000a receives a still image from the host and the still image is displayed, the logic circuit 20 operates based on the internal clock INT_CLK output from the oscillator 10.

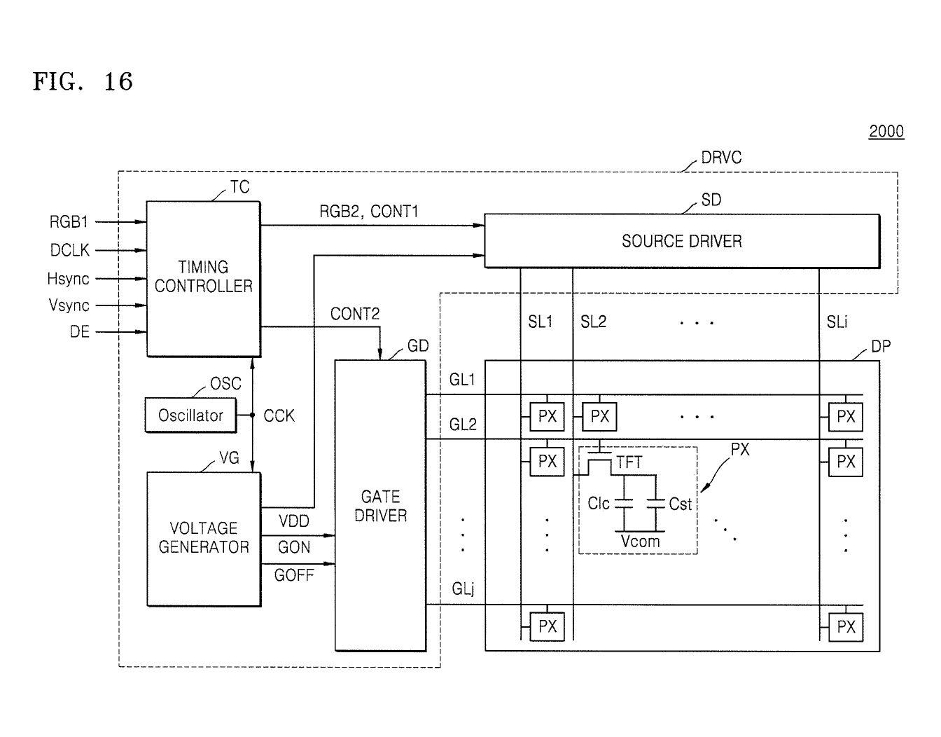

FIG. 16 illustrates an embodiment of a display device 2000 which includes a display panel DP and a driving circuit DRVC. The display panel DP displays an image in units of frames. The display panel DP may be, for example, a liquid crystal display (LCD), a light emitting diode (LED) display, an organic LED (OLED) display, an active-matrix OLED (AMOLED) display, a flexible display, or another kind of flat panel display (FPD). For the sake of convenience, the display device 2000 will be described as corresponding to an LCD panel.

The display panel DP includes gate lines GL1 to GLj arranged in a row direction, source lines SL1 to SLi arranged in a column direction, and pixels PX formed at intersections of the gate lines GL1 to GLj and the source lines SL1 to SLi. Each pixel PX includes a thin film transistor (TFT), an LC capacitor Clc connected to a drain of the TFT, and a storage capacitor Cst. A common voltage Vcom may also be connected to the LC capacitor C1c and the storage capacitor Cst.

When the gate lines GL1 to GLj are sequentially scanned, TFTs of pixels PX connected to a selected gate line are turned on and a gray scale voltage corresponding to data RGB2 of the pixels is applied to the source lines SL1 to SLi. The gray scale voltage is applied to the LC capacitor C1c and the storage capacitor Cst through the TFTs of the corresponding pixels PX, and a displaying operation is performed based on the voltages stored in the LC capacitor C1c and the storage capacitor Cst.

The driving circuit DRVC includes a source driver SD, a gate driver GD, a timing controller TC, a voltage generator VG, and an oscillator OSC. The driving circuit DRVC may be implemented by one or a plurality of semiconductor chips.

The timing controller TC receives image data RGB1, a horizontal synchronizing signal Hsync, a vertical synchronizing signal Vsync, a clock signal DCLK, and a data enable signal DE from an external device (for example, a host device) and generates control signals CNT1 and CNT2 for controlling the gate driver GD and the source driver SD based on the received signals. In addition, the timing controller TC generates pixel data RGB2 obtained by converting a format of the image data RGB1 received from the outside to be suitable for an interface specification with the source driver SD and transmits the pixel data RGB2 to the source driver SD.

The gate driver GD and the source driver SD drive the pixels PX of the display panel DP in accordance with the control signals CNT1 and CNT2 from the timing controller TC.

The source driver SD drives the source lines SL1 to SLi of the display panel DP based on the source driver control signal CNT1. The source driver SD generates a plurality of gamma voltages and outputs a gamma voltage corresponding to the pixel data RGB2 to the source lines SL1 to SLi of the display panel DP. The source driver SD may be formed of a single chip or a plurality of source driving chips.

The gate driver GD sequentially scans the gate lines GL1 to GLj of the display panel DP. The gate driver GD activates a selected gate line by applying a gate-on voltage GON to the selected line. The source driver SD outputs gamma voltages corresponding to pixels connected to the activated gate line. Therefore, an image may be displayed on the display panel DP in units of horizontal lines, that is, by units of rows.

The voltage generator VG generates voltages used by the driving circuit DRVC and the display panel DP. The voltage generator VG may generate the gate-on voltage GON, a gate-off voltage GOFF, the common voltage Vcom, and an analog power source voltage VDDA. The gate-on voltage GON and the gate-off voltage GOFF are provided to the gate driver GD and are used for generating gate signals applied to the gate lines GL1 to GLj. The common voltage Vcom may be commonly provided to the pixels PX of the display panel DP.

As illustrated in FIG. 16, the common voltage Vcom may be provided to one end of each of the LC capacitor C1c and the storage capacitor Cst. The analog power source voltage VDDA may be used when the source driver SD operates. In addition, the voltage generator VG may generate a power source voltage used for an oscillator OSC or the timing controller TC.

The oscillator OSC generates the clock signal CLK and may provide the generated clock signal CLK to the timing controller TC or the voltage generator VG. The clock signal CLK may be provided to the source driver SD or the gate driver GD. The timing controller TC divides the frequency of the clock signal CLK and may generate the control signals CNT1 and CNT2 based on the frequency divided clock signal. The voltage generator VG may generate the voltages based on the frequency divided clock signal.

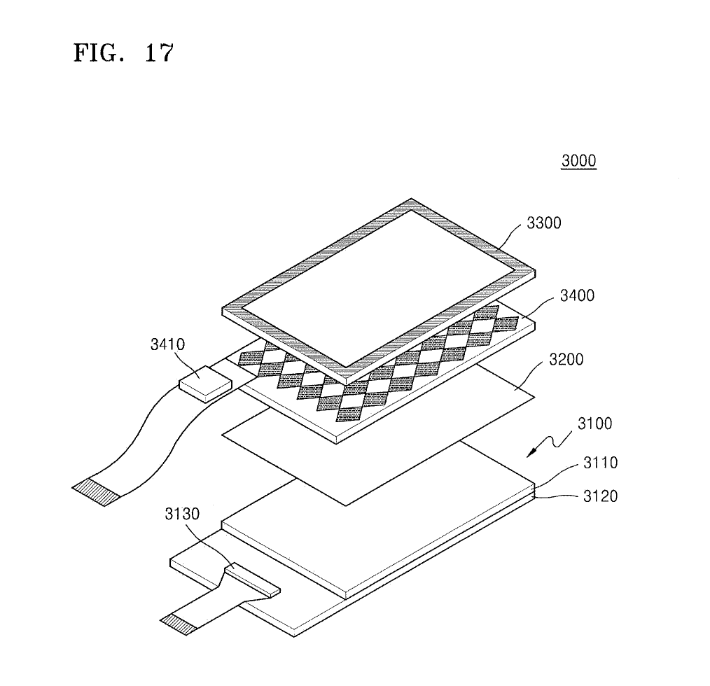

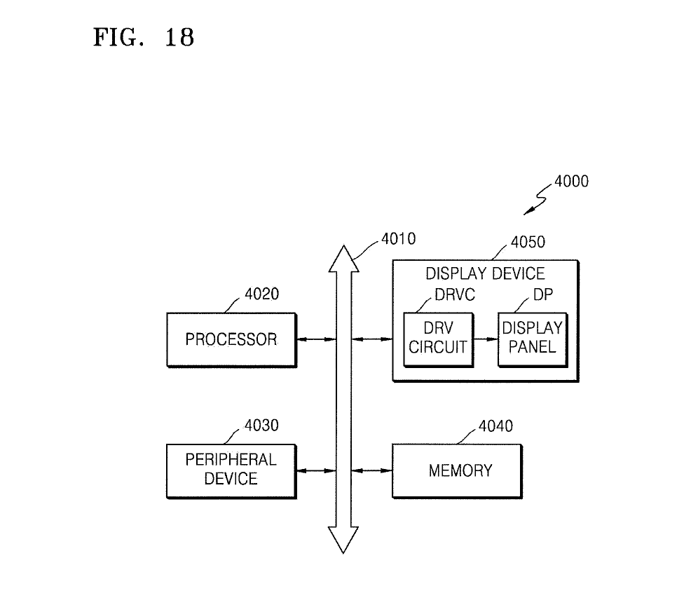

FIG. 17 illustrates an embodiment of a display module 3000 which includes a display device 3100, a polarizing plate 3200, and a window glass 3300. The display device 3100 includes a display panel 3110, a printed board 3120, and a display driving integrated circuit (IC) 3130.

The window glass 3300 may be commonly formed, for example, of acryl or enhanced glass to protect the display module 3000 against external shock or scratches caused by repetitive touches. The polarizing plate 3200 may be provided in order to improve an optical characteristic of the display panel 3100. The display panel 3110 may be formed by patterning a transparent electrode on the printed board 3120. The display panel 3110 includes a plurality of pixels for displaying a frame. The display panel 3110 may be, for example, an LCD panel, an organic light emitting diode (OLED), an electrochromic display (ECD), a digital mirror device (DMD), an actuated mirror device (AMD), a grating light value (GLV), a plasma display panel (PDP), an electroluminescent display (ELD), a light emitting diode (LED) display, a vacuum fluorescent display (VFD), or another type of display panel.

The display driving IC 3130 includes an oscillator in accordance with any of the aforementioned embodiments, e.g., oscillator 10 in FIG. 1 or oscillator 10a in FIG. 9.

According to the current example embodiment, the display driving IC 3130 is illustrated as corresponding to one chip. In another example embodiment, the display driving IC 3130 may be formed of a plurality of chips. In addition, the display driving IC 3130 may be mounted, for example, on a glass printed board of a chip-on-glass (COG) type, a chip-on-film (COF) type, or a chip-on-board (COB) type.

The display module 3000 may further include a touch panel 3400 and a touch controller 3410. The touch panel 3400 may be formed, for example, by patterning a transparent electrode such as indium tin oxide (ITO) on a glass substrate or a polyethylene terephthalate (PET) film. The touch controller 3410 senses generation of a touch on the touch panel 3400, calculates touch coordinates, and transmits the calculated touch coordinates to a host or other control circuit. The touch controller 3410 may be integrated, for example, in one semiconductor chip with the display driving IC 3130, or the touch controller 3410 may be implemented in a separate chip.

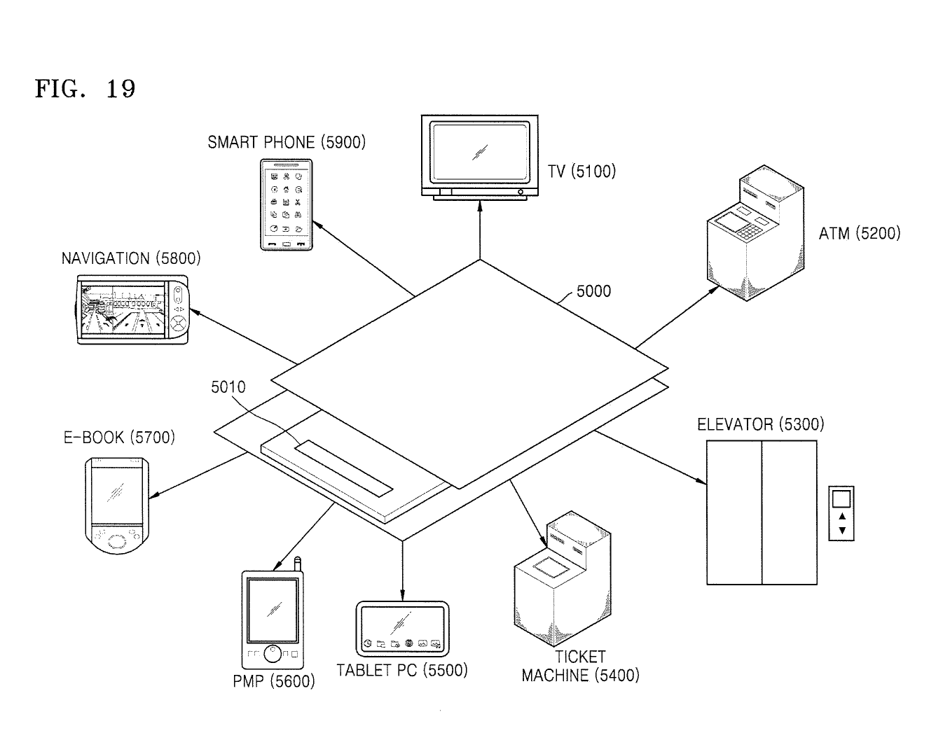

FIG. 18 illustrates a display system 4000 which includes a processor 4020 electrically connected to a system bus 4010, a display device 4050, a peripheral device 4030, and a memory 4040.

The processor 4020 controls input and output of data of the peripheral device 4030, the memory 4040, and the display device 4050, and may process image data transmitted among the devices. The display device 4050 includes a display panel DP and a display driving IC DRVC, stores image data items applied through the system bus 4010 in a frame memory or a line memory in the display driving IC DRVC, and displays the stored image data items on the display panel DP. The display device 4050 may be, for example, the display device 2000 of FIG. 16. The display driving IC DRVC may include an oscillator in accordance with any of the aforementioned embodiments, e.g., oscillator 10 in FIG. 1 or oscillator 10a in FIG. 9.

The peripheral device 4030 may be a device for converting moving pictures or still images of a camera, a scanner, and/or a web camera to electrical signals. The image data obtained through the peripheral device 4030 may be stored in the memory 4040 or may be displayed on a panel of the display device 4050 in real time. The memory 4040 may include a volatile memory device such a dynamic random access memory (DRAM) and/or a non-volatile memory device such as a flash memory. The memory 4040 may be a DRAM, a parameter RAM (PRAM), a magnetoresistive RAM (MRAM), a resistive RAM (ReRAM), a ferroelectric RAM (FRAM), a NOR flash memory, a NAND flash memory, or a fusion flash memory (for example, a memory obtained by combining a static RAM (SRAM) buffer, a NAND flash memory, and a NOR interface logic). The memory 4040 stores image data obtained by the peripheral device 4030 or may store image signals processed by the processor 4020.

In accordance with one example embodiment, the display system 4000 may be provided in an electronic product such as a tablet, PC, TV, monitor, or another type of electronic product that displays images.

FIG. 19 illustrates examples of various types of electronic products which may include a display device 5000 according to an example embodiment. The display device 5000 may be included in or coupled to, for example, a TV 5100, an automated teller machine (ATM) 5200 that automatically performs cash-based transactions of a bank, an elevator 5300, a ticket machine 5400 used in a subway, a tablet PC 5500, a portable multimedia player (PMP) 5600, an e-book 5700, a navigation 5800, and a smart phone 5900. In addition, the display device 5000 may be mounted in a wearable electronic device.

The generators, controllers, comparators, trimming units, and other processing features of the embodiments disclosed herein may be implemented in logic which, for example, may include hardware, software, or both. When implemented at least partially in hardware, the generators, controllers, comparators, trimming units, and other processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the generators, controllers, comparators, trimming units, and other processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods described herein.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

1. An oscillator, comprising:
a reference current generator to generate a reference current;
a reference voltage generator to generate a reference voltage based on the reference current;
a comparison voltage generator to generate a comparison voltage obtained by delaying and inverting a clock signal based on the reference current; and
a clock signal generator to compare the comparison voltage with the reference voltage and generate the clock signal based on a result of the comparison.

2. The oscillator as claimed in claim 1, wherein a frequency of the clock signal is based on a voltage level of the reference voltage and a voltage change speed of the comparison voltage.

3. The oscillator as claimed in claim 1, wherein the reference current generator includes a bandgap reference circuit to generate a voltage or a current insensitive to an applied power source voltage or a change in temperature.

4. The oscillator as claimed in claim 1, wherein the reference current generator is to generate the reference current to have a substantially uniform slope with respect to a change in temperature.

5. The oscillator as claimed in claim 1, wherein the reference current generator includes a variable resistor to control a temperature coefficient of the reference current.

6. The oscillator as claimed in claim 5, wherein the reference current generator is to control a resistance value of the variable resistor based on a temperature coefficient control signal.

7. The oscillator as claimed in claim 1, wherein:
the clock signal generator includes a comparator to compare the comparison voltage with the reference voltage and output a result of the comparison, and
a bias current applied to the comparator is based on the reference current.

8. The oscillator as claimed in claim 7, wherein a temperature characteristic of a response speed of the comparator is based on a temperature characteristic of the reference current.

9. The oscillator as claimed in claim 1, wherein the reference voltage generator includes:
a first current mirror circuit to generate a first bias current proportional to the reference current by mirroring the reference current; and
a reference voltage output circuit including a reference resistance, the reference voltage output circuit to output the reference voltage generated based on the first bias current and the reference resistance.

10. The oscillator as claimed in claim 9, wherein the reference voltage generator includes a voltage coefficient controller to control a characteristic of the first bias current for a power source voltage.

11-20. (canceled)

21. An oscillator, comprising:
a reference current generator to generate a reference current and to control a temperature characteristic of the reference current;
a reference voltage generator to generate a reference voltage based on the reference current;
a comparison voltage generator to generate a comparison voltage obtained by delaying and inverting a clock signal based on the reference current;
a comparing circuit to compare the comparison voltage with the reference voltage and to output a result of the comparing; and
a latch circuit to latch a result of the comparison and to generate the clock signal.

22. The oscillator as claimed in claim 21, wherein the reference current generator is to control a temperature coefficient of the reference current based on a temperature coefficient control signal.

23. The oscillator as claimed in claim 22, wherein the reference current generator includes a variable resistor having a resistance value which changes based on the temperature coefficient control signal.

24. The oscillator as claimed in claim 22, wherein the temperature coefficient control signal is to be set based on a difference between a measured temperature characteristic of the oscillator and a target temperature characteristic.

25. The oscillator as claimed in claim 21, wherein the comparing circuit includes a comparator to receive the comparison voltage and the reference voltage as inputs and to be biased based on the reference current.

26-27. (canceled)

28. A display driving circuit, comprising:
an oscillator to generate a clock signal;
a timing controller to divide a frequency of the clock signal and to generate a timing control signal; and
a driving circuit to output a driving voltage based on the timing control signal, wherein the oscillator includes:
a bandgap reference circuit to generate a reference current having a temperature characteristic based on a temperature coefficient control signal; and
a clock generating circuit to generate a clock signal having a frequency based on the reference current.

29. The oscillator as claimed in claim 28, further comprising:
trimming logic; and
a comparison voltage generator to generate a comparison voltage by delaying and inverting the clock signal based on the reference current, wherein:
the clock generating circuit is to compare the comparison voltage with the reference voltage and to generate the clock signal based on a result of the comparison, and
the trimming logic is to trim a voltage level of the comparison voltage or a delay time of a comparison signal output from the comparison voltage generator.

30. The oscillator as claimed in claim 28, further comprising:
a clock generator to generate the clock signal based on a current generated by mirroring the reference current, and
trimming logic to linearly vary a mirroring ratio between the generated current and the reference current based on a thermometer code signal.

31. The oscillator as claimed in claim 28, wherein the clock generating circuit includes:
a reference voltage generator to receive the reference current and to generate a reference voltage;
a comparison voltage generator to receive the reference current and to generate a first comparison voltage and a second comparison voltage that transition in manner complementarily to each other;
a comparator to compare the first comparison voltage and the second comparison voltage with the reference voltage and to output a result of the comparison; and
a latch circuit to latch the result of the comparison and to output the latched result as the clock signal.

32. The oscillator as claimed in claim 28, further comprising:
a selector to select one of a clock signal output from the oscillator or an external clock signal, wherein the timing controller is to generate the timing control signal based on a signal output from the selector.

33-38. (canceled)
